(19) United States
(12) Patent Application Publication
(10) Pub. No.: US 2022/0051726 A1
(43) Pub. Date: Feb. 17, 2022

(54) STORAGE STRUCTURE AND ERASE METHOD THEREOF

(71) Applicant: Wuhan Xinxin Semiconductor Manufacturing Co., Ltd., Wuhan, Hubei Province (CN)

(72) Inventor: JONGBAE JEONG, Shanghai (CN)

(21) Appl. No.: 17/050,457

(22) PCT Filed: Dec. 17, 2019
(86) PCT No.: PCT/CN2019/125965

§ 371 Date: Oct. 26, 2020

(30) Foreign Application Priority Data
Dec. 2, 2019 (CN) 201911215946.9

(51) Int. Cl. G11C 16/16; G11C 16/10; G11C 16/34

(52) U.S. Cl. CPC G11C 16/16; G11C 16/3477; G11C 16/345; G11C 16/102

(57) ABSTRACT

The invention provides a storage structure and an erase method thereof, which can perform an erase operation on memory blocks B₁ . . . Bₙ, where n is an integer greater than or equal to 2. The storage structure includes a first memory bank, a second memory bank and a controller, wherein the memory blocks are sequentially alternately arranged in the first memory bank and the second memory bank. The controller is used to control the memory blocks to sequentially undergo an erase operation. The erase operation includes sequentially performing a first process and a second process. When memory block Bᵢ undergoes the second process, the memory block Bᵢ₊₁ undergoes the first process, where i ∈ [1, n−1].

### BACKGROUND OF THE INVENTION

### 1. Field of the Invention

The present invention relates to semiconductor devices, and in particular, to a storage structure and an erase method thereof.

### 2. Description of the Prior Art

The main features of flash memories are fast working speed, small cell area, high integration and good reliability. A flash memory can be rewritten more than 100,000 times, and data can be reliably maintained for more than 10 years. The two main types of flash memory on the market today are NOR and NAND non-volatile flash memory. The NOR flash memory (Nor Flash) has a small cell area and short read (write) operation time, and thus is widely used. Current Nor Flash memories are based on floating-gate flash memory technology. In order to save size, the storage area is in a matrix form logically divided into many memory blocks. In erase operations, memory blocks are sequentially erased block by block. Usually the erase operation includes a pre-programing step, an erase step and an over-erase correction step (OEC). The pre-programming step changes all binary values in the memory block; the erase step applies a larger erase pulse to the memory block, so that the threshold voltage of the memory block is lower than a specific level value; and the over-erase correction step repairs an over-erased memory block to prevent the threshold voltage from being too low.

FIG. 1 is a schematic structural diagram of a related storage structure 100. As shown in FIG. 1, the storage structure 100 includes two memory banks, namely a first memory bank Bank0 and a second memory bank Bank1. The first memory bank Bank0 and the second memory bank Bank1 are both coupled to a chip controller 110. The chip controller 110 is configured to control the first memory bank Bank0 and the second memory bank Bank1 to perform operations such as read, write, and erase. A total of n (n≥2) memory blocks are arranged in the first memory bank Bank0 and the second memory bank Bank1. The memory blocks in the first memory bank Bank0 and the second memory bank Bank1 are evenly and sequentially distributed, such that the memory blocks are sequentially stored in the first memory bank Bank0 and are then sequentially stored in the second memory bank Bank1. For convenience of description, the n memory blocks are sequentially numbered as: B₁, B₂ . . . Bₙ, where B₁, B₂ . . . B_{n/2} are arranged in the first memory bank Bank0, and B_{(n/2+1)}, B_{(n/2+2)} . . . Bₙ are arranged in the second memory bank Bank1.

FIG. 2 is a flowchart 200 of performing an entire erasing of the storage structure 100. As shown in FIG. 2, the erase operations are sequentially performed in the order of B₁, B₂, . . . Bₙ. First, a pre-program step is performed on the memory block B₁, then an erase step is performed on the memory block B₁, and finally an over-erase correction step (OEC) is performed on the memory block B₁. After the three steps are completed, the erasing of the memory block B₁ is completed (Erase Done). Next, the pre-programming step, the erase step, and the over-erase correction step are sequentially performed on the memory block B₂ to complete the erasing of the memory block B₂. Then, the above three steps are sequentially performed until the last memory block Bₙ is erased, and the storage structure 100 is entirely erased.

The above erase method of the storage structure 100 performs the three erase steps individually for each memory block. The erase operation on a next memory block will not begin until the erase operation on a previous memory block has been completed. As there are usually many blocks within the storage structure (for example, n=256), it will take a lot of time to complete the entire erasing of the storage structure 100, and the erasing efficiency is low.

Since the erase operation requires these three steps and the non-volatile flash memory also integrates a large number of memory blocks, the entire erase operations of the non-volatile flash memory is very time-consuming compared to read/write operations. Thus, how to improve the overall erasing efficiency of the non-volatile flash memory becomes a problem which needs to be solved.

### SUMMARY OF THE INVENTION

An objective of the present invention is to provide a storage structure and an erase method thereof, so as to solve the problem of low efficiency during the erasing of the nonvolatile flash memory.

In order to achieve the above goal, the present invention provides a storage structure capable of performing an erase operation on memory blocks B₁, B₂ . . . Bₙ, where n is an integer greater than or equal to 2, and the storage structure comprises: a first memory bank; a second memory bank and a controller, where the memory blocks are sequentially alternately arranged in the first memory bank and the second memory bank. The controller is used to control the memory blocks to undergo an erase operation, where the erase operation includes a first process and a second process, which are sequentially performed.

The set manner includes: when memory block Bᵢ undergoes the second process, memory block Bᵢ₊₁ undergoes the first process, where i ∈ [1, n−1].

Optionally, after the memory block B₁ completes the first process, the memory block B₁ undergoes the second process, and at the same time, the memory block B₂ undergoes the first process; after that, the remaining memory blocks are processed in the same way such that after the memory block Bᵢ completes the second process and the memory block Bᵢ₊₁ completes the first process, the memory block Bᵢ₊₁ undergoes the second process; after the memory block Bₙ completes the first process, the memory block Bₙ undergoes the second process.

Optionally, the first process includes a pre-programming step and an erase step, and the second process includes an over-erase correction step.

Optionally, the first process includes a pre-programming step, and the second process includes an erase step and an over-erase correction step.

Optionally, the numbers of memory blocks in the first memory bank and the second memory bank are the same or different.

Optionally, the storage structure includes M memory banks, where M is greater than or equal to 2.

Optionally, the controller includes:
a first memory bank controller, coupled to the first memory bank for controlling the first memory bank;
a second memory bank controller, coupled to the second memory bank for controlling the second memory bank;
a chip controller connected to the first memory bank controller and the second memory bank controller, which can control the memory blocks to sequentially undergo an erase operation.

Optionally, the storage structure is a Nor flash.

The invention also provides a method for erasing a storage structure, which is used to perform an erase operation on memory blocks B₁ . . . Bₙ, where n is an integer greater than or equal to 2. The method includes:
sequentially alternately arranging the memory blocks in the first memory bank and the second memory bank;
controlling the memory blocks to sequentially undergo an erase operation;
wherein the erase operation includes a first process and a second process, and when a memory block Bᵢ undergoes the second process, a memory block Bᵢ₊₁ undergoes the first process, wherein i ∈ [1, n−1].

Optionally, the erase method of the storage structure is used for entire erasing of the storage structure.

In the storage structure and erase method provided by the present invention, an erase operation can be performed on memory blocks B₁ . . . Bₙ, where n is an integer greater than or equal to 2. The storage structure includes a first memory bank, a second memory bank and a controller, wherein the memory blocks are sequentially alternately arranged in the first memory bank and the second memory bank. The controller is used to control the memory blocks to sequentially undergo an erase operation. The erase operation includes sequentially performing a first process and a second process. When a memory block Bᵢ undergoes the second process, a memory block Bᵢ₊₁ undergoes the first process, where i ∈ [1, n−1]. Two adjacent memory blocks undergo the first process and the second process simultaneously, thereby saving erasing time when performing an entire erase of the storage structure. This improves the erasing efficiency without requiring any additional circuits, such that there is no increase in costs.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic structural diagram of a storage structure according to the related art.

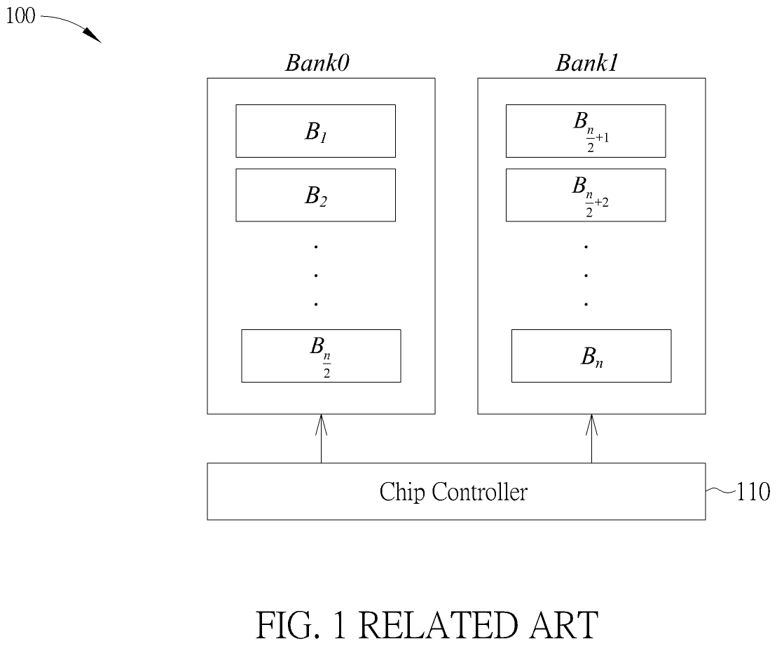

FIG. 2 is a flowchart of the erase method of the storage structure in FIG. 1.

FIG. 3 is a schematic structural diagram of a storage structure according to a first embodiment of the present invention.

FIG. 4 is a flowchart of a method for erasing a storage structure according to a first embodiment of the present invention.

FIG. 5 is a flowchart of a method for erasing a storage structure according to a second embodiment of the present invention.

### DETAILED DESCRIPTION

The specific embodiments of the present invention will be described in more detail below with reference to the schematic diagrams. The advantages and features of the invention will become clearer from the following description. It should be noted that the drawings are in a very simplified form and all use inaccurate proportions, which are only used to facilitate and clearly assist the description of the embodiments of the present invention. The numbers of the memory blocks and banks are intended to aid explanation of the scheme, and it does not mean that the corresponding numbers of the memory blocks and the banks must be set as in the figures, nor does it mean that the numbering of the blocks must be in accordance with the numbering method in order to realize this invention.

### EMBODIMENT I

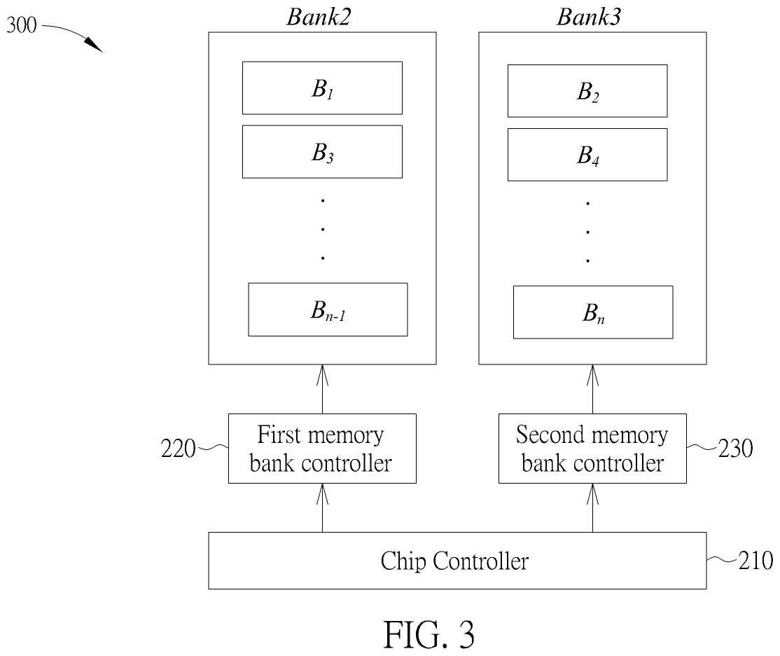

FIG. 3 is a schematic structural diagram of a storage structure provided by this embodiment. The storage structure 300 is, for example, a Nor Flash, which includes at least two banks, namely a first bank Bank2 and a second bank Bank3. The first bank Bank2 and the second bank Bank3 store a total of n (n≥2) memory blocks, and the n memory blocks are evenly distributed in the first bank Bank2 and the second bank Bank3. The memory blocks therein are alternately arranged in the first bank Bank2 and the second bank Bank3 according to the numbering sequence. For ease of description, the n memory blocks are sequentially numbered as: B₁, B₂ . . . Bₙ. In this embodiment, n is an even number. In this way, the memory blocks B₁, B₃ . . . Bₙ₋₁ are arranged in the first memory Bank2, and the memory blocks B₂, B₄ . . . Bₙ are arranged in the second memory Bank3. At this time, the numbers of the memory blocks stored in the first bank Bank2 and the second bank Bank3 are the same.

Obviously, when n is an odd number, there will be one more memory block stored in the first memory bank Bank2 than the second memory bank Bank3, but this does not affect the implementation of the present invention.

The storage structure 300 further includes a controller, which comprises a chip controller 210, a first memory bank controller 220 and a second memory bank controller 230. The first memory bank controller 220 is connected to and controls the first memory bank Bank2, while the second memory bank controller 230 is connected to and controls the second memory bank Bank3. The chip controller 210 is coupled to the first memory bank controller 220 and the second memory bank controller 230 and is configured to control the first memory bank Bank2 and the second memory bank Bank3 to perform operations such as read, write, and erase. Because addresses of the first memory bank Bank2 and the second memory bank Bank3 and corresponding bias conditions (voltages required to be applied to the source, drain, or gate) are different, this embodiment relies on the chip controller 210 to control both the first memory bank controller 220 and the second memory bank controller 230. The first memory bank controller 220 and the second memory bank controller 230 control the first memory bank Bank2 and the second memory bank Bank3, respectively, such that the chip controller 210 can simultaneously perform operations upon the memory blocks in the first memory bank Bank2 and the second memory bank Bank3.

It should be understood, however, that according to existing integrated circuit design and manufacturing technologies, the first memory bank controller 220, the second memory bank controller 230, and the chip controller 210 may be integrated into a single control unit, or may be modularized as two, four, or multiple control units. This should be understood by those skilled in the art. The embodiment detailed here merely provides a preferred solution.

This embodiment also provides an erase method of the storage structure 300, which is used to perform entire erasing of the storage structure 300. Specifically, the memory blocks are sequentially alternately arranged in the first memory bank Bank2 and the second memory bank Bank3. When the storage structure 300 needs to be erased entirely, the controller controls the memory blocks B₁, B₂ . . . Bₙ to sequentially undergo an erase operation, wherein the erase operation includes a first process and a second process. When the first process and the second process have both been performed on a memory block, the erase operation is completed for the memory block. When the memory block Bᵢ undergoes the second process, the memory block Bᵢ₊₁ undergoes the first process, where i ∈ [1, n−1]. In other words, for the two adjacent memory blocks, memory block B₁ undergoes the second process and memory block Bᵢ₊₁ undergoes the first process simultaneously. After the memory block Bᵢ completes the second process and the memory block Bᵢ₊₁ completes the first process, the erasing of the memory block Bᵢ is completed; then, the memory block Bᵢ₊₁ undergoes the second process, and simultaneously the memory block Bᵢ₊₂ undergoes the first process. This continues in a pipeline manner until the erasing of the memory block Bₙ is completed, thereby entirely erasing the storage structure 300.

In this embodiment, the first process includes a pre-programing step, while the second process includes an erase step and an over-erase correction step (OEC), which must be performed sequentially.

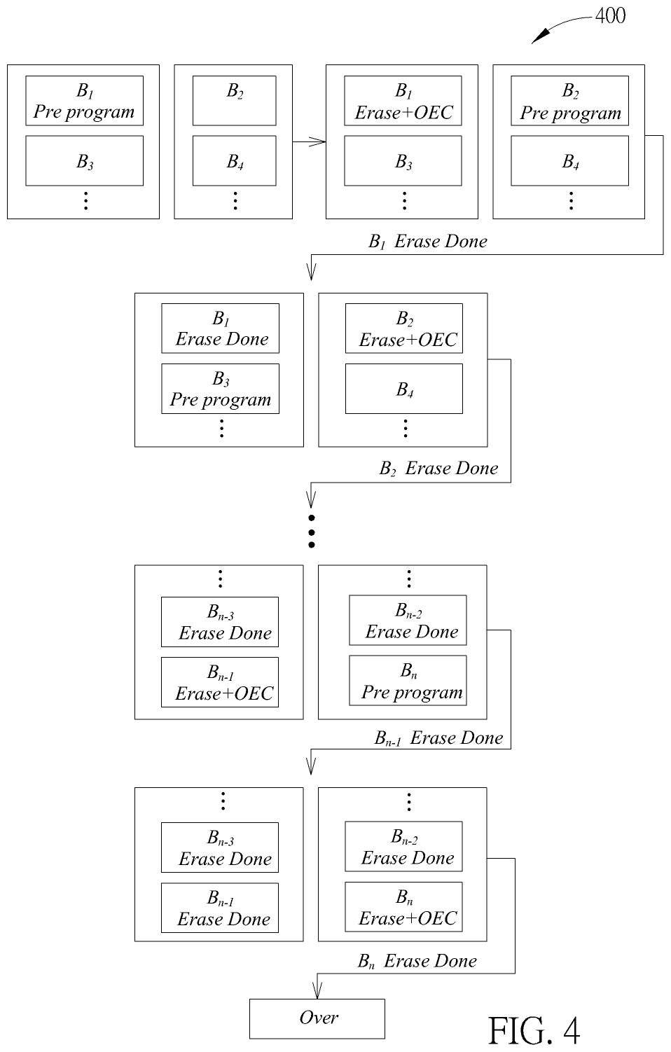

FIG. 4 is a flowchart 400 of the erase method of the storage structure 300 according to this embodiment. The erase method of the storage structure 300 provided in this embodiment will be described in detail with reference to FIGS. 3 and 4.

As shown in FIG. 4, the memory block B₁ first undergoes a pre-programming step (first process); after the memory block B₁ completes the pre-programming step, the memory block B₁ undergoes an erase step followed by an over-erase correction step. At the same time, the memory block B₂ undergoes a pre-programming step. After the memory block B₁ completes the erase step and the over-erase correction step, the erasing of the memory block B₁ is completed (B₁ Erase Done). The memory block B₂ has also completed the pre-programming step, and will then undergo the erase step as well as the over-erase correction step, while the memory block B₃ undergoes the pre-programming step. After the memory block B₂ completes the erase step and the over-erase correction step, the erasing of the memory block B₂ is completed (B₂ Erase Done). At the same time, the memory block B₃ completes the pre-programming step. These steps will be sequentially performed until the memory block Bₙ₋₁ has completed the erase step and the over-erase correction step and the memory block Bₙ has completed the pre-programming step, so the erasing of the memory block Bₙ₋₁ is completed (Bₙ₋₁ Erase Done). To complete entire erasing of the storage structure, the memory block Bₙ needs to undergo the erase step and the over-erase correction step.

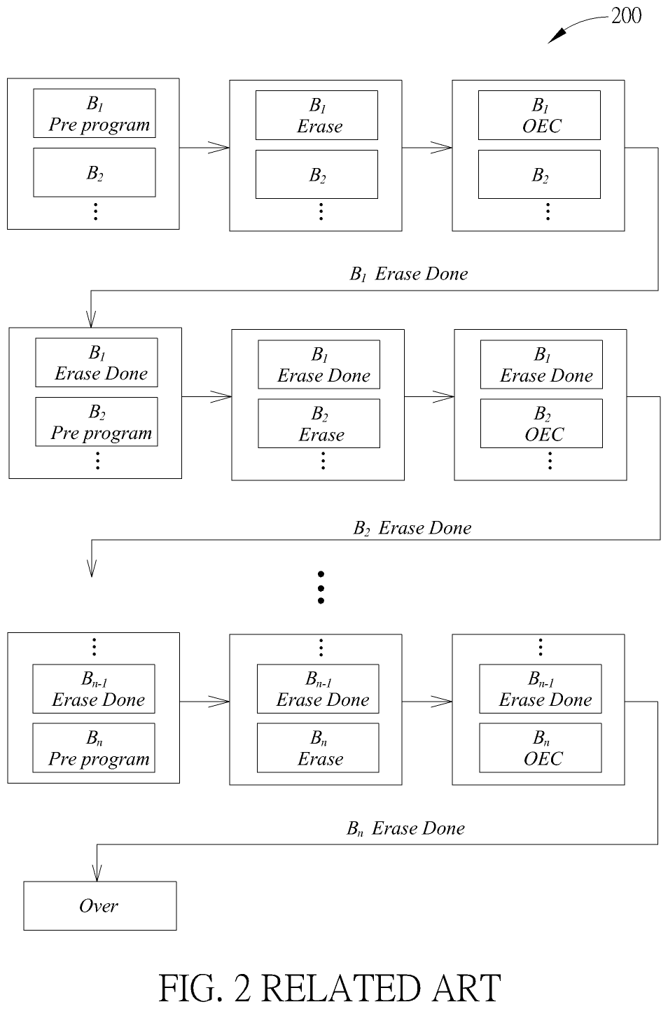

The erase method shown in FIG. 2 requires each memory block to complete its erase operation separately before a next memory block begins its erase operation. In the embodiment shown in FIG. 4, because the memory block Bᵢ undergoes the second process and the memory block Bᵢ₊₁ undergoes the first process simultaneously, erasing time is saved, which improves erasing efficiency.

In order to prove that the erase method of the storage structure provided in this embodiment improves the erasing efficiency, the following assumptions and calculations are made:

Assume n=256, the time of the pre-programming step t1=50 ms, the time of the erase step t2=80 ms, and the time of the over-erase repair step t3=20 ms;

The time T1 required to erase the entire storage structure by using the erase method shown in FIG. 2 is:

T1=(50 ms+80 ms+20 ms)*256=38.4 s

The time T2 required to erase the entire storage structure by using the erase method shown in FIG. 4 is:

T2=((80 ms+20 ms)*256)+50 ms=25.65 s

It can be seen that, compared with the erase method of the storage structure provided in FIG. 2, the erase method of the storage structure provided by this embodiment can improve the erasing efficiency by about 33.2%.

### EMBODIMENT II

In this embodiment, the first process includes a pre-programming step and an erase step, while the second process includes an over-erase correction step. When the memory block Bᵢ undergoes the second process, only the over-erase correction step is performed. When the memory block Bᵢ₊₁ undergoes the first process, the pre-programming step and the erase step are sequentially performed.

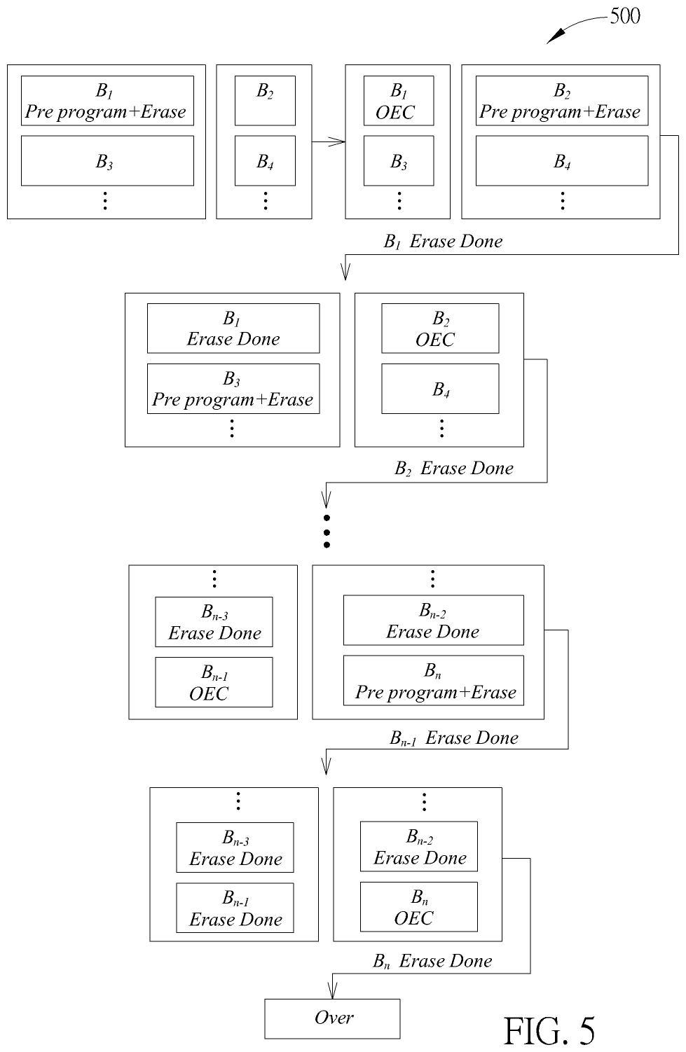

FIG. 5 is a flowchart 500 of the erase method of the storage structure 300 according to this embodiment. The erase method of the storage structure 300 provided in this embodiment will be described in detail with reference to FIGS. 3 and 5.

As shown in FIG. 5, first, the memory block B₁ sequentially undergoes the pre-programming step and the erase step; after the memory block B₁ completes the pre-programming step and the erase step, the memory block B₁ undergoes the over-erase correction step, while the memory block B₂ sequentially undergoes a pre-programming step and an erase step; after the memory block B₁ completes the over-erase correction step and the memory block B2 completes the pre-programming step and the erase step, the erasing of the memory block B₁ is completed (B₁ Erase Done). Next, the memory block B₂ undergoes the over-erase correction step, and the memory block B₃ undergoes the pre-programming step and the erase step; after the memory block B₂ completes the over-erase correction step and the memory block B₃ completes the pre-programming step and erase step, the erasing of the memory block B₂ is completed (B₂ Erase Done). Then, these steps are sequentially performed until the memory block Bₙ₋₁ has completed the over-erase correction step and the memory block Bₙ has completed the pre-programming step and the erase step. Then, the erasing of the memory block Bₙ₋₁ is completed (Bₙ₋₁ Erase Done). The memory block Bₙ needs to undergo the over-erase correction step separately. After the memory block Bₙ completes the over-erase correction step, the erasing of the memory block Bₙ is completed (Bₙ Erase Done), and the storage structure 200 has completed the entire erasing.

In order to prove that the erase method of the storage structure provided in this embodiment improves the erasing efficiency, the same assumptions and calculations as those in the first embodiment are made:

Assume n=256, the time of the pre-programming step t1=50 ms, the time of the erase step t2=80 ms, and the time of the over-erase repair step t3=20 ms;

The time T2 required to erase the entire storage structure by using the erase method of the storage structure provided in FIG. 5 is:

T2=(50 ms+80 ms)*256+20 ms=33.3 s

It can be seen that, compared with the erase method of the storage structure provided in FIG. 2, the erase method of the storage structure provided by this embodiment can improve the erasing efficiency by about 13.3%.

The saved erasing time calculated with reference to Embodiments I and II are reference values. The flash memory may have different pre-programming time, erasing time, and over-erase correction time depending on the manufacturing process and operation mode. Therefore, the erasing time saved in the embodiment II is not necessarily the same, and may be lower than in Embodiment I.

In addition, the number of banks in Embodiments I and II is not limited to two, and may be M, where M is preferably a multiple of 2. When M is not a multiple of 2, the present invention can also be implemented by applying the inventive method to most memory banks in a storage structure.

In summary, in the storage structure and the erase method provided by the embodiments of the present invention, an erasing operation can be performed on sequentially numbered memory blocks B₁ . . . Bₙ, where n is an integer greater than or equal to 2, and the storage structure includes a first memory bank, a second memory bank, and a controller, wherein the memory blocks are sequentially alternately stored in the first memory bank and the second memory bank, and the controller is used to control the memory blocks. The erase operation is performed sequentially on the memory blocks, and includes a first process and a second process. The erasing operation comprises the memory block Bᵢ undergoing the second process while the memory block Bᵢ₊₁ undergoes the first process, where i ∈ [1, n−1]. Erasing time of the entire erasing of the storage structure is saved, which improves the erasing efficiency, while requiring no additional circuits.

Those skilled in the art will readily observe that numerous modifications and alterations of the device and method may be made while retaining the teachings of the invention. Accordingly, the above disclosure should be construed as limited only by the metes and bounds of the appended claims.

1. A storage structure capable of performing an erase operation on memory blocks B₁ . . . Bₙ, where n is an integer greater than or equal to 2, the storage structure comprising a first memory bank, a second memory bank, and a controller, wherein the memory blocks are sequentially alternately arranged in the first memory bank and the second memory bank, and the controller is configured to control the memory blocks to undergo an erase operation, wherein the erase operation comprises sequentially performing a first process and a second process;
wherein when memory block Bᵢ undergoes the second process, the memory block Bᵢ₊₁ undergoes the first process, where i ∈ [1, n−1].

2. The storage structure according to claim 1, wherein after the memory block B₁ completes the first process, the memory block B₁ undergoes the second process and the memory block B₂ undergoes the first process at the same time; then the erase operation is performed on the remaining memory blocks sequentially until the memory block Bᵢ₊₁ undergoes the second process and the memory block Bₙ undergoes the first process at the same time, then the memory block Bₙ undergoes the second process.

3. The storage structure according to claim 1, wherein the first process includes a pre-programming step and an erase step, and the second process includes an over-erase correction step, wherein the erase step is performed after the pre-programing step.

4. The storage structure according to claim 1, wherein the first erase step includes a pre-programming step, and the second process includes an erase step and an over-erase correction step, wherein the over-erase correction step is performed after the erase step.

5. The storage structure according to claim 1, wherein the numbers of memory blocks in the first memory bank and the second memory bank are the same or different.

6. The storage structure according to claim 1, wherein the storage structure comprises M memory banks, wherein M is greater than or equal to 2.

7. The storage structure according to claim 1, wherein the controller comprises:
a first memory bank controller, coupled to the first memory bank for controlling the first memory bank;
a second memory bank controller, coupled to the second memory bank for controlling the second memory bank;
a chip controller coupled to the first memory bank controller and the second memory bank controller and capable of simultaneously operating on the memory blocks in the first memory bank and the second memory bank.

8. The storage structure according to claim 1, wherein the storage structure is a Nor flash.

9. A method of erasing a storage structure, used to perform an erase operation on memory blocks B₁ . . . Bₙ, where n is an integer greater than or equal to 2, and the method comprises:
sequentially alternately arranging the memory blocks in the first memory bank and the second memory bank; and
controlling the memory blocks to sequentially undergo an erase operation;
wherein the erase operation includes sequentially performing a first process and a second process, and when a memory block Bᵢ undergoes the second process, a memory block Bᵢ₊₁ undergoes the first process, wherein, i ∈ [1, n−1].

10. The method for erasing a storage structure according to claim 9, wherein the method for erasing the storage structure is used for entire erasing of the storage structure.

11. The storage structure according to claim 2, wherein the first process includes a pre-programming step and an erase step, and the second process includes an over-erase correction step, wherein the erase step is performed after the pre-programing step.

12. The storage structure according to claim 2, wherein the first erase step includes a pre-programming step, and the second process includes an erase step and an over-erase correction step, wherein the over-erase correction step is performed after the erase step.

13. The storage structure according to claim 2, wherein the numbers of memory blocks in the first memory bank and the second memory bank are the same or different.

14. The storage structure according to claim 2, wherein the storage structure comprises M memory banks, wherein M is greater than or equal to 2.

15. The storage structure according to claim 7, wherein the storage structure is a Nor flash.
